(19) United States
(12) Patent Application Publication
(10) Pub. No.: US 2026/0096253 A1
(43) Pub. Date: Apr. 2, 2026

(54) LIGHT-EMITTING DIODE AND LIGHT-EMITTING DEVICE

(71) Applicant: XIAMEN SAN'AN OPTOELECTRONICS CO., LTD., Xiamen (CN)

(72) Inventors: Xu SUN, Xiamen (CN); Jenlung YANG, Xiamen (CN); CHAN-CHAN LING, Xiamen (CN)

(21) Appl. No.: 19/342,594

(22) Filed: Sep. 28, 2025

(30) Foreign Application Priority Data
Sep. 30, 2024 (CN) 202411388261.5

(51) Int. Cl. H10H 20/84; H10H 20/831

(52) U.S. Cl. CPC H10H 20/84; H10H 20/831

(57) ABSTRACT

A light-emitting diode includes: a semiconductor stack layer, including a first semiconductor layer, a light-emitting layer and a second semiconductor layer sequentially stacked from bottom to top; a transparent conductive layer, disposed over the second semiconductor layer; a protective layer, disposed over the transparent conductive layer; and a first electrode, disposed over the protective layer, and including a pad part and an extension part. The protective layer defines a first opening and second openings on the pad part and the extension part, respectively, and the first electrode is electrically connected to the second semiconductor layer through the first opening and the second openings. The second openings include multiple first opening parts and a second opening part, the second opening part is defined on an end facing away from the pad part, and a size of the second opening part is greater than that of each first opening part.

### CROSS-REFERENCE TO RELATED APPLICATION

This application claims priority to Chinese Patent Application No. 202411388261.5, filed on Sep. 30, 2024, which is herein incorporated by reference in its entirety.

### TECHNICAL FIELD

The disclosure relates to the field of semiconductor manufacturing technologies, and more particularly to a light-emitting diode and a light-emitting device.

### BACKGROUND

Light Emitting Diode (LED) is usually made of semiconductors such as gallium nitride (GaN), gallium arsenide (GaAs), gallium phosphide (GaP), and gallium arsenide phosphide (GaAsP). A core of LED is a PN junction with luminous properties. Under forward voltage, electrons are injected from a N region into a P region, and holes are injected from the P region into the N region. Some of the minority carriers that enter the other region recombine with the majority carriers to emit light. LED has advantages of high luminous intensity, high efficiency, small size, and long service life, and is considered to be one of the most promising light sources at present.

A manufacturing process of early GaN LED chips includes four processes, namely, mesa etching (MESA), manufacturing a transparent conductive layer (such as indium tin oxide, abbreviated as ITO), manufacturing electrodes, and manufacturing a protective layer. In recent years, in order to improve the luminous efficiency of LED, it is known that there are four new processes in the industry, namely, mesa etching (MESA), manufacturing a transparent conductive layer, manufacturing a protective layer, and manufacturing electrodes. At present, in the LED industry, in order to achieve effective current spreading, a design of multiple spreading electrodes is generally adopted. Since an end of each spreading electrode is often a high current density region, in the new four processes, the end of the spreading electrode is often prone to electrostatic discharge (ESD) explosion points and burns due to excessive charge concentration, which in turn causes chip failure and dead light. Therefore, how to further optimize the design of the protective layer to improve the reliability of the light-emitting diode chip is a technical problem that those skilled in the art need to solve.

### SUMMARY

In view of defects and disadvantages of light-emitting diodes in the related art, the disclosure provides a light-emitting diode and a light-emitting device, to thereby improve the reliability of the chip.

In an embodiment of the disclosure, a light-emitting diode is provided, including a semiconductor stack layer, a transparent conductive layer, a protective layer, and a first electrode. The semiconductor stack layer includes a first semiconductor layer, a light-emitting layer and a second semiconductor layer sequentially stacked in that order from bottom to top. The transparent conductive layer is disposed over the second semiconductor layer. The protective layer is disposed over the transparent conductive layer. The first electrode is disposed over the protective layer, and includes a first pad part and a first extension part.

The protective layer defines a first opening on the first pad part and defines second openings on the first extension part, to thereby expose a part of an upper surface of the second semiconductor layer located on the first pad part and a part of an upper surface of the transparent conductive layer located on the first extension part. The first electrode is electrically connected to the second semiconductor layer through the first opening and the second openings.

The second openings of the protective layer includes multiple first opening parts and at least one second opening part, the at least one second opening part is defined on an end of the first extension part facing away from the first pad part, and a size of the at least one opening part is greater than a size of each first opening part.

In another embodiment of the disclosure, a light-emitting device is provided, including the above light-emitting diode.

The light-emitting diode provided by the disclosure is designed with differentiated sizes of the second openings of the protective layer located on the first extension part of the first electrode, specifically by increasing the size of the second opening part located at the end of the first extension part facing away from the first pad part. On the one hand, it can avoid the occurrence of ESD explosion points due to excessive charge concentration at the end of the spreading electrode (i.e., the first extension part of the first electrode), thereby improving an anti-static impact capability of the chip, and ensuring the reliability of the light-emitting diode. On the other hand, it can also allow the current at the end of the spreading electrode to spread as evenly as possible to the surroundings through the large-sized second opening part, thereby improving the overall current uniformity of the light-emitting diode, and thereby improving the luminous efficiency of the light-emitting diode chip.

Other features and advantages of the disclosure will be set forth in the following description, and in part will be apparent from the description, or may be learned by practicing the disclosure.

### BRIEF DESCRIPTION OF DRAWINGS

In order to more clearly illustrate technical solutions in embodiments of the disclosure or in the related art, drawings required for use in the embodiments or the description of the related art are briefly introduced below. Apparently, the drawings described below are some of the embodiments of the disclosure. For those skilled in the art, other drawings can be obtained based on these drawings without creative work.

FIG. 1 illustrates a schematic diagram from a perspective of a top view of a light-emitting diode according to an embodiment 1 of the disclosure.

FIG. 2 illustrates a schematic sectional structural diagram of the light-emitting diode along a A-A′ line in FIG. 1.

FIG. 3 illustrates a schematic partial enlarged diagram of a box region in FIG. 2.

FIG. 4 illustrates a schematic sectional structural diagram of the light-emitting diode along a B-B′ line in FIG. 1.

FIG. 5 illustrates a photomask diagram of the light-emitting diode according to the disclosure.

FIG. 6A illustrates a schematic diagram of a current flow path of a light-emitting diode in the related art.

FIG. 6B illustrates a schematic diagram of a current flow path of the light-emitting diode according to the embodiment 1 of the disclosure.

FIG. 7 illustrates a schematic diagram from a perspective of a top view of a light-emitting diode according to an embodiment 2 of the disclosure.

FIG. 8 illustrates a schematic sectional structural diagram of the light-emitting diode along a A-A′ line in FIG. 7.

FIG. 9 illustrates a schematic diagram from a perspective of a top view of a light-emitting diode according to an embodiment 3 of the disclosure.

FIG. 10 illustrates a schematic sectional structural diagram of the light-emitting diode along a A-A′ line in FIG. 9.

FIG. 11 illustrates a schematic diagram from a perspective of a top view of a light-emitting diode according to an embodiment 4 of the disclosure.

FIG. 12 illustrates a schematic sectional structural diagram of the light-emitting diode along a A-A′ line in FIG. 11.

FIG. 13 illustrates a schematic diagram from a perspective of a top view of another light-emitting diode according to the embodiment 4 of the disclosure.

FIG. 14 illustrates a schematic sectional structural diagram of the light-emitting diode along a A-A′ line in FIG. 13.

FIG. 15 illustrates a schematic diagram from a perspective of a top view of still another light-emitting diode according to the embodiment 4 of the disclosure.

FIG. 16 illustrates a schematic sectional structural diagram of the light-emitting diode along a A-A′ line in FIG. 15.

FIG. 17 illustrates a schematic diagram from a perspective of a top view of yet another light-emitting diode according to the embodiment 4 of the disclosure.

FIG. 18 illustrates a schematic sectional structural diagram of the light-emitting diode along a A-A′ line in FIG. 17.

### DETAILED DESCRIPTION OF EMBODIMENTS

Technical solutions of the disclosure will be clearly and completely described below in conjunction with drawings in embodiments of the disclosure and through multiple specific implementation methods.

### Embodiment 1

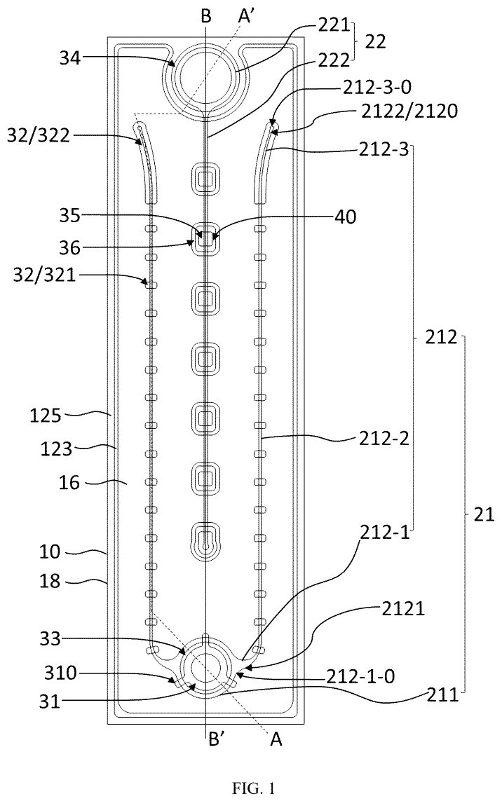

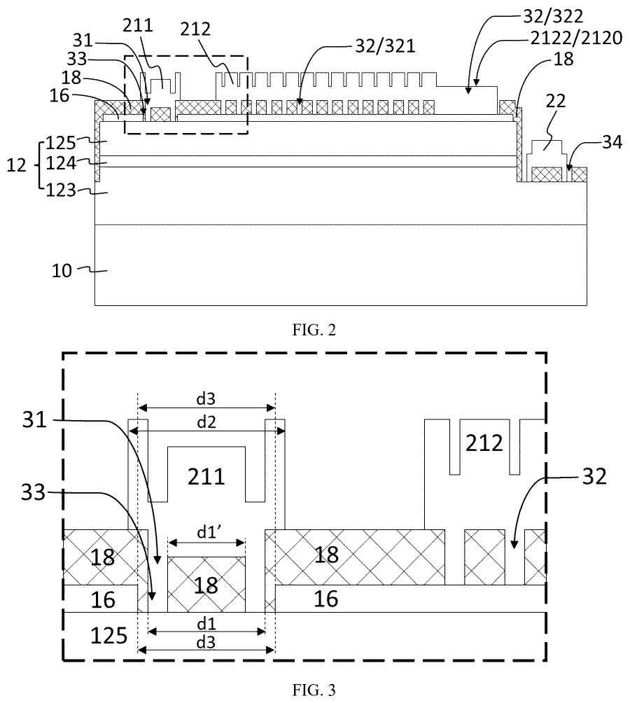

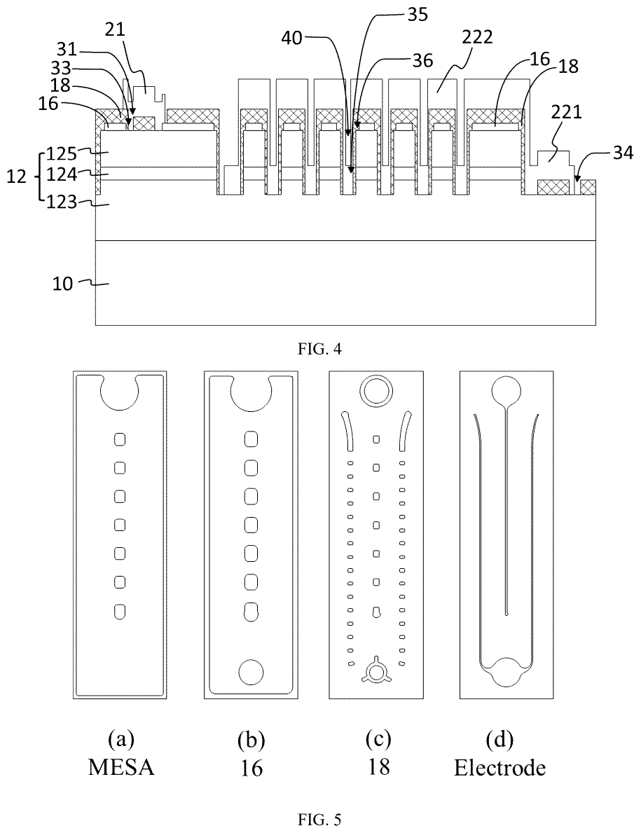

Referring to FIG. 1 to FIG. 4, FIG. 1 illustrates a schematic diagram from a perspective of a top view of a light-emitting diode according to an embodiment 1 of the disclosure. FIG. 2 illustrates a schematic sectional structural diagram of the light-emitting diode along a A-A′ line in FIG. 1. FIG. 3 illustrates a schematic partial enlarged diagram of a box region in FIG. 2. FIG. 4 illustrates a schematic sectional structural diagram of the light-emitting diode along a B-B′ line in FIG. 1. In order to achieve at least one of the above advantages or other advantages, an embodiment of the disclosure provides a light-emitting diode, the light-emitting diode at least includes a substrate 10, a semiconductor stack layer 12, a first electrode 21, a second electrode 22. A transparent conductive layer 16 and a protective layer 18. The first electrode 21 includes a pad part 211 (i.e., first pad part) and an extension part 212 (i.e., first extension part). The second electrode 22 includes a pad part 221 (i.e., second pad part) and an extension part 222 (i.e., second extension part. The extension part 212 of the first electrode 21 includes a first end 2121 connected to the pad part 211 of the first electrode 21 and a second end 2122 facing away from the pad part 211 of the first electrode 21.

Specifically, the substrate 10 can be a transparent substrate, a non-transparent substrate or a semi-transparent substrate. The substrate 10 may be selected from, but not limited to, sapphire, aluminum nitride, gallium nitride, silicon, silicon carbide, and glass. A surface structure of the substrate 10 can be a planar structure or a patterned structure. In some embodiments, the substrate 10 may be a combined patterned substrate. In other embodiments, the substrate 10 may be thinned or removed to form a thin film chip.

The semiconductor stack layer 12 is disposed on an upper surface of the substrate 10. The semiconductor stack layer 12 includes a first semiconductor layer 123, a light-emitting layer 124 and a second semiconductor layer 125 sequentially stacked in that order. The first semiconductor layer 123 is disposed over the substrate 10. As a layer grown on the substrate 10, the first semiconductor layer 123 can be doped with n-type impurifies, for example, a gallium nitride semiconductor layer of silicon (Si). In some embodiments, a buffer layer can be disposed between the first semiconductor layer 123 and the substrate 10. In other embodiments, the first semiconductor layer 123 can be bonded to the substrate 10 through a bonding layer.

The light-emitting layer 124 is disposed over the first semiconductor layer 123, and the light-emitting layer 124 can be a quantum well (QW) structure. In some embodiments, the light-emitting layer 124 can also be a multiple quantum well (MQW) structure, and the MQW structure includes multiple QW layers and multiple quantum barrier layers arranged alternately and repeatedly. In addition, a composition and a thickness of the well layers in the light-emitting layer 124 determine a wavelength of the generated light. In particular, by adjusting the composition of the well layers, a light-emitting layer that generates different colors of light such as ultraviolet light, blue light, green light, and yellow light can be provided.

The second semiconductor layer 125 is disposed over the light-emitting layer 124, the second semiconductor layer 125 can be doped with p-type impurifies, for example, a gallium nitride semiconductor layer of magnesium (Mg). Although the first semiconductor layer 123 and the second semiconductor layer 125 can be a single-layer structure, individually, the disclosure is not limited to this, the first semiconductor layer 123 and the second semiconductor layer 125 can be a multiple-layer structure, and can also include a superlattice layer. In addition, in other embodiments, when the first semiconductor layer 123 is doped with the p-type impurifies, the second semiconductor layer 125 can be doped with the n-type impurifies, that is, the first semiconductor layer 123 is a P-type semiconductor layer, and the second semiconductor layer 125 is a N-type semiconductor layer.

In the embodiment, the second semiconductor layer 125 includes a mesa for forming the second electrode 22 and multiple through holes 40 penetrating through the second semiconductor layer 125 and the light-emitting layer 124, thereby exposing a part surface of the first semiconductor layer 123, and a number of the through holes 40 is in a range of 1-15. The transparent conductive layer 16 is disposed over the second semiconductor layer 125, and defines a third opening 33 on a corresponding position of the pad part 211 of the first electrode 21, thereby exposing a part of an upper surface of the second semiconductor layer 125 located on a pad region of the first electrode 21. A size of the third opening 33 is smaller than that of the pad part 211 of the first electrode 21. The transparent conductive layer 16 defines a sixth opening 36 on a corresponding position of the extension part 222 of the second electrode 22, and a size of the sixth opening 36 is greater than a size of each through hole 40. Outside the through holes 40, the transparent conductive layer 16 and the protective layer 18 are sandwiched between the extension part 222 of the second electrode 22 and the second semiconductor layer 125. The protective layer is disposed over the transparent conductive layer 16, and covers an upper surface of a mesa of the transparent conductive layer 16 and a side wall connecting the mesa and the upper surface of the second semiconductor layer 125, that is, basically covers the surface of the entire device. Moreover, a first opening 31 and second openings 32 are defined on corresponding positions of the pad part 211 and the extension part 212 of the first electrode 21, thereby exposing a part of the upper surface of the second semiconductor layer 125 located on the pad region of the first electrode 21 and a part of the upper surface of the transparent conductive layer 16 located on an extension region of the first electrode 21, so that the pad part 211 of the first electrode 21 is in contact with the second semiconductor layer 125 through the first opening 31. The extension part 212 of the first electrode 21 is in contact with the transparent conductive layer 16 through the second openings 32. The protective layer 18 defines a fourth opening 34 and fifth openings 35 at the corresponding positions of the pad part 221 and the extension part 222 of the second electrode 22. The fifth openings 35 are defined in the through holes 40, respectively. A size of each fifth opening 35 is smaller than the size of each through hole 40. In each through hole 40, the protective layer 18 covers a side wall of each through hole 40. The first electrode 21 and the second electrode 22 are defined on the protective layer 18. Specifically, the pad part 221 of the second electrode 22 is disposed over the mesa and is in contact with the first semiconductor layer 123 through the fourth opening 34. As shown in FIG. 1 and FIG. 4, the fourth opening 34 can be an annular opening, the extension part 222 of the second electrode 22 is disposed over the protective layer 18 located above the second semiconductor layer 125, and is in contact with the first semiconductor layer 123 through the fifth openings 35 and the through holes 40. The pad part 211 of the first electrode 21 is in contact with the second semiconductor layer 125 through the first opening 31, and the extension part 212 of the first electrode 21 is in contact with the transparent conductive layer 16 through the second openings 32. As shown in FIG. 1 to FIG. 3, the first opening 31 can be an annular opening.

The first electrode 21 and the second electrode 22 may be metal electrodes, that is, the first electrode 21 and the second electrode 22 are made of metal materials, for example, at least one of nickel, gold, chromium, titanium, platinum, palladium, rhodium, iridium, aluminum, tin, indium, tantalum, copper, cobalt, iron, ruthenium, zirconium, tungsten and molybdenum, or at least one of alloys or laminates selected from the above materials. As an example, in the embodiment, the first electrode 21 may be a P electrode, and the second electrode 22 may be an N electrode.

The transparent conductive layer 16 may include at least one of indium tin oxide (ITO), zinc-doped indium tin oxide (ZITO), zinc indium oxide (ZIO), gallium indium oxide (GIO), zinc tin oxide (ZTO), fluorine-doped tin oxide (FTO), aluminum-doped zinc oxide (AZO), and gallium-doped zinc oxide (GZO). As an example, in the embodiment, the transparent conductive layer 16 is an ITO (indium tin oxide semiconductor transparent conductive film) layer formed by evaporation or sputtering process.

The material of the protective layer 18 may include a non-conductive material. The non-conductive material is an inorganic material or a dielectric material. The inorganic material may include silica gel. The dielectric material includes an electrically insulating material such as aluminum oxide, silicon nitride, silicon oxide, titanium oxide, or magnesium fluoride. For example, the protective layer 18 may be silicon dioxide, silicon nitride, titanium oxide, tantalum oxide, niobium oxide, barium titanate, or a combination thereof, and the combination thereof may be, for example, a Bragg reflector (DBR) formed by repeatedly stacking two materials with different refractive indices. As an example, in the embodiment, the material of the protective layer 18 is silicon dioxide (SiO₂). The protective layer 18 has different effects depending on the designed positions. In the structure of the light-emitting diode described in the embodiment, the protective layer 18 protects the surface of the light-emitting diode on the one hand, and on the other hand, serves as a current blocking layer to suppress the current over-injection under the electrode and increase the current diffusion of the transparent conductive layer 16. Considering the requirements of both, a thickness d of the protective layer 18 is λ/4n×(2k−1), where λ represents an emission wavelength of the light-emitting layer 124, n represents a refractive index of the protective layer 18, and k represents a natural number greater than 1. In an embodiment, a value of k is 2-3, and the corresponding thickness of the protective layer 18 is in a range of 150 nanometers (nm) to 500 nm. When the thickness of the protective layer 18 is too small, it is not conducive to playing the role of current blocking layer and protection. When the thickness of the protective layer 18 is too large, the absorption of the material itself will increase the light loss.

Referring to FIG. 3, FIG. 3 illustrates a schematic partial enlarged diagram of a box region in FIG. 2, which shows a partial enlarged view of the first electrode 21. The transparent conductive layer 16 defines a third opening 33 at a position corresponding to the pad part 211 of the first electrode 21, and the protective layer 18 defines a first opening 31 at a position corresponding to the pad part 211 of the first electrode 21. The protective layer 18 covers an inner side wall of the third opening 33, a diameter of the first opening 31 is smaller than a diameter of the third opening 33, thereby further improving the brightness of the light-emitting diode. Specifically, the first opening 31 is an annular structure, an inner diameter of the first opening 31 is defined as d1′, an outer diameter of the first opening 31 is defined as d1, a diameter of the pad part 211 of the first electrode 21 is defined as d2, and a diameter of the third opening 33 is defined as d3. The relationship between the four diameters is: d2>d3>d1>d1′, so that an upper surface of the pad part 211 of the first electrode 21 is stepped. It should be noted that, in some other embodiments, the diameter of the first opening 31 may be larger than the diameter of the third opening 33. In this design, the adhesion between the electrode and the epitaxial layer can be effectively increased, and the risk of the electrode and the attachment interface falling off during wire bonding can be reduced. Similarly, in the embodiment, the outer diameter and the inner diameter of the first opening 31 are smaller than the diameter of the third opening 33, thereby further improving the brightness of the light-emitting diode. In some other embodiments, the outer diameter of the first opening 31 may be larger than the diameter of the third opening 33, and the inner diameter of the first opening 31 may be smaller than the diameter of the third opening 33, which can also effectively increase the adhesion between the electrode and the epitaxial layer and improve the electrode wire bonding capability.

In an embodiment, the first opening 31 of the protective layer 18 located below the pad part 211 of the first electrode 21 may have at least one finger 310 extending in a direction facing away from the pad part 211, and the number of the finger 310 is in a range of 1 to 20. At the position of the finger 310, the pad part 211 of the first electrode 21 is in contact with the second semiconductor layer 125 and the transparent conductive layer 16 at the same time. Through the finger 310, the pad part 211 of the first electrode 21 can be in contact with the transparent conductive layer 16, which can increase a contact area between the pad part 211 of the first electrode 21 and the transparent conductive layer 16, which is beneficial to the diffusion of current, thereby further alleviating a current congestion effect on the first electrode 21 and reducing the risk of metal precipitation and electrode burning.

In the embodiment, the protective layer 18 of the light-emitting diode protects the light-emitting diode from being damaged on the one hand, and can directly serve as a current blocking layer on the other hand, for suppressing the current over-injection under the electrode and increasing the current diffusion of the transparent conductive layer 16. The first electrode 21 is in directly contact with the semiconductor layer in the pad region, which effectively increases the adhesion between the electrode and the epitaxial layer, and reduces the risk of the electrode and the attachment interface falling off during wire bonding. The pad part 211 of the first electrode 21 adopts a design of multiple steps to effectively buffer the impact force of the wire bonding and reduce the impact and damage to the pad part 211 during the wire bonding process. The extension part 212 of the first electrode 21 is located on the protective layer 18, and is in contact with the transparent conductive layer 16 through the openings in the protective layer 18, so that the extension part 212 of the first electrode 21 forms a step shape with upper and lower rises, thereby increasing an angle of light emission at a position of the extension part 212 of the first electrode 21, and improving a light extraction efficiency. At the same time, since the extension part 212 of the first electrode 21 has a high step and a low step undulation distribution, a contact area between the electrode and other objects can be reduced, thereby effectively reducing the damage to the extension part 212 of the first electrode 21 during the later film inversion, transportation and transfer, and reducing the dirt on the extension part 212 of the first electrode 21.

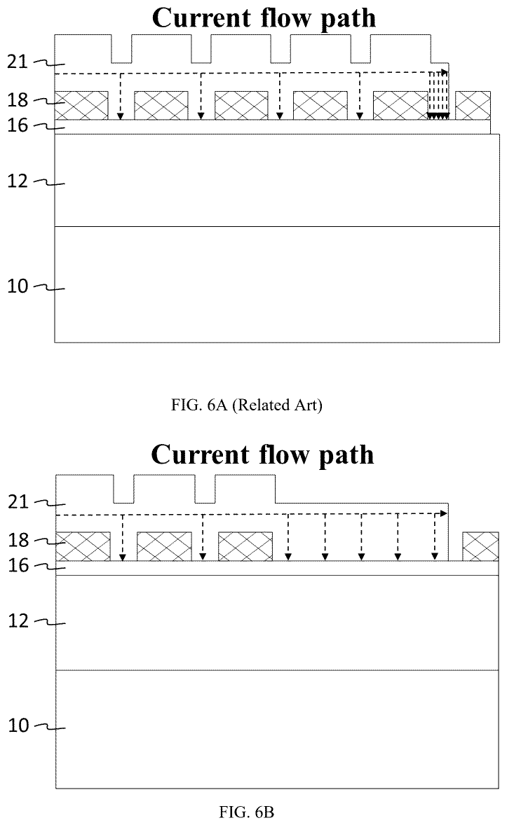

In the disclosure, the protective layer 18 defines multiple second openings 32 below the extension part 212 of the first electrode 21. The second openings 32 are sequentially arranged at intervals along a direction gradually extending away from the pad part 211 of the first electrode 21. The extension direction of the pad part 211 of the first electrode 21 is also a direction from the first end 2121 of the pad part 211 of the first electrode 21 to the second end 2122 of the pad part 211 of the first electrode 21. The second openings 32 are spaced apart from one another by intervals. The second openings 32 and the intervals are alternately arranged along the extension direction of the pad part 211 of the first electrode 21. The numbers of the second openings 32 and the intervals are 1 to 25. In the embodiment, the intervals of the second openings 32 have the same size, and the second openings 32 include multiple first opening parts 321 and at least one second opening part 322. The second opening part 322 is defined at an end 2120 of the extension part 212 of the first electrode 21 facing away from the pad part 211 of the first electrode 21, that is, the second opening part 322 is defined below the second end 2122 of the extension part 212 of the first electrode 21, and a size of the second opening part 322 is greater than a size of each first opening part 321. In the embodiment, the multiple first opening parts 321 have the same size. The disclosure designs the size of the second openings 32 located on the extension part 212 of the first electrode 21 of the protective layer 18 to be differentiated, specifically by increasing the size of the second opening part 322 located at the end 2120 of the extension part 212 of the first electrode 21 facing away from the pad part 211 of the first electrode 21. On the one hand, since the end of the spreading electrode (i.e., extension part 212) is often a high current density region, the second opening part 322 with the largest size is disposed below the second end 2122 of the extension part 212 of the first electrode 21, so that the occurrence of ESD explosion points at the end of the spreading electrode due to excessive charge concentration can be avoided, thereby improving the anti-static impact capability of the chip, and further ensuring the reliability of the light-emitting diode. On the other hand, the current at the end of the spreading electrode can spread as evenly as possible through the large-sized second opening part 322, which avoids direct injection of current at the end of the spreading electrode, promotes lateral expansion of the current, and improves the overall current uniformity of the light-emitting diode at the same time, thereby improving the reliability and the luminous efficiency of the light-emitting diode chip. Referring to FIG. 6 for details, FIGS. 6A and 6B illustrate schematic diagrams of a current flow path of the light-emitting diode. Specifically, FIG. 6A is the four processes of known mesa etching (MESA), transparent conductive layer (such as ITO), protective layer and electrode mentioned in the background. It can be seen that at the second end 2122 of the extension part 212 of the first electrode 21/the end 2120 of the extension part 212 of the first electrode 21, the current is easily too concentrated, thereby generating ESD explosion points. FIG. 6B is a schematic diagram of the current flow path of the light-emitting diode provided by the disclosure. By increasing the size of the second opening part 322 at the end 2120 of the extension part 212 of the first electrode 21 facing away from the pad part 211 of the first electrode 21, the current can be diffused as evenly as possible to the surroundings through the large-sized second opening part 322 at the end of the spreading electrode, thereby improving the reliability and the luminous efficiency of the light-emitting diode chip. In addition, the protective layer 18 is disposed over the transparent conductive layer 16 first, and then the first electrode 21 is formed, a probability of oxidation of the active metal in the electrode structure during the production process of the protective layer 18 can be reduced. It should be noted that in the disclosure, there may be more than one second opening part 322, for example, there may be more than two second opening parts 322, and the size of any second opening part 322 is larger than the size of any first opening part 321, and the selection may be made according to specific actual needs, and the disclosure is not limited thereto. For example, when the size of the second opening part 322 is less than 10 times the size of the first opening part 321, there is one second opening part 322. When the size of the second opening part is more than 10 times the size of the first opening part, there are more than two second opening parts 322.

In the disclosure, the size of the second opening part 322 is at least twice the size of the first opening part 321. In an embodiment, the size of the second opening part 332 is 2 to 20 times the size of the first opening part 321. In an embodiment, the size of the second opening part 332 is 2 to 15 times the size of the first opening part 321. In an embodiment, the size of the second opening part 332 is 4 to 12 times the size of the first opening part 321. Optionally, the size of the second opening part 322 is at least 5 times, 8 times, 10 times, 12 times, or 14 times the size of the first opening part 321. By limiting the multiple of the size of the second opening part 322 and the size of the first opening part 321, the current can be more effectively diffused to the surroundings through the large-sized second opening part 322, thereby avoiding the ESD explosion points caused by the charge concentration phenomenon, improving the overall current uniformity of the light-emitting diode at the same time, and improving the reliability and the luminous efficiency of the light-emitting diode chip.

Please continue to refer to FIG. 1. The second opening part 322 and the extension part 212 of the first electrode 21 have an overlapping part, and a length of the overlapping part accounts for 2% to 40% of a length of the extension part 212 of the first electrode 21, or an area of the overlapping part accounts for 2% to 40% of an area of the extension part 212 of the first electrode 21. In an embodiment, the proportion is 5% to 25%. In another embodiment, the proportion is 10% to 20%. Optionally, the length proportion of the overlapping part or the area proportion of the overlapping part can be, for example, 12%, 14%, 16% or 18%. The length or area proportion of the overlapping part between the second opening part 322 and the extension part 212 of the first electrode 21 further promotes the current to be more effectively diffused to the surroundings through the large-sized second opening part 322, thereby improving the overall current uniformity on the first electrode 21, and further improving the luminous efficiency of the light-emitting diode chip. It should be noted that, since the extension part 212 of the first electrode 21 does not include a simple straight part, for example, in the embodiment, the extension part 212 of the first electrode 21 includes a first curved part 212-1, a straight part 212-2, and a second curved part 212-3, an end of the first curved part 212-1 is connected to the pad part 211 of the first electrode 21, and the other end of the first curved part 212-1 is connected to the straight part 212-2. An end of the straight part 212-2 is connected to the first curved part 212-1, and another end of the straight part 212-2 is connected to the second curved part 212-3. An end of the second curved part 212-3 is connected to the straight part 212-2, and another end of the second curved part 212-3 is gradually bent in a direction facing away from the second electrode 22. More specifically, the first curved part 212-1 includes an extension part 212-1-0, an end of the extension part 212-1-0 is connected to the pad part 211 of the first electrode 21, and another end of the extension part 212-1-0 is connected to the straight part 212-2. The second curved part 212-3 includes a circular end part 212-3-0. The length and area of the extension part 212 of the first electrode 21 mentioned above include a length and an area of the entire section from the extension part 212-1-0 to the circular end part 212-3-0.

A method for manufacturing the light-emitting diode of the disclosure mainly includes four processes of mesa etching (MESA), manufacturing a transparent conductive layer 16, manufacturing a protective layer 18, and manufacturing an electrode. FIG. 5 shows corresponding mask patterns involved in these four processes, which are briefly described below.

First, a semiconductor stack layer 12 is provided, which generally includes a substrate 10, a first semiconductor layer 123, a light-emitting layer 124, and a second semiconductor layer 125.

Next, referring to the pattern shown in FIG. 5(a), a first electrode region and a second electrode region are defined on a surface of the semiconductor stack layer 12, and an empty area is removed to form a mesa of the second electrode 22 and multiple through holes 40.

Next, referring to the pattern shown in FIG. 5(b), a transparent conductive layer 16 is disposed over the second semiconductor layer 125 of the semiconductor stack layer 12, the mesa region is etched away, and an opening 33 is defined in the pad region of the first electrode region, and openings 36 are defined at positions corresponding to the through holes 40, respectively.

Next, referring to the pattern shown in FIG. 5(c), a protective layer 18 is disposed over the transparent conductive layer 16. The protective layer 18 covers sidewalls of the through holes 40, a sidewall between the transparent conductive layer 16 and the mesa, and a surface of the mesa. An opening 31 is defined on the pad region of the first electrode region, openings 32 are defined on the extension region of the first electrode region, an opening 34 is defined on the mesa, and openings 35 are defined on the extension region of the second electrode region. The openings 35 are defined in the through holes 40 respectively, and a size of each opening 35 is smaller than a size of each through hole 40. In an embodiment, the opening 31 is an annular structure, and an inner diameter d1′ and an outer diameter d1 of the annular structure are both smaller than a diameter d3 of the opening 33. In an embodiment, the openings 32 include multiple first opening parts 321 of the same size and a second opening part 322. The second opening part 322 is located below the second end 2122 of the extension part 212 of the first electrode 21, and a size of the second opening part 322 is larger than a size of the first opening part 321.

Next, referring to the pattern shown in FIG. 5(d), a first electrode 21 and a second electrode 22 are manufactured on the protective layer 18. The pad part 211 of the first electrode 21 is in contact with the second semiconductor layer 125 through the first opening 31, the pad part 211 of the first electrode 21 is in contact with the second semiconductor layer 125 and the protective layer 18, and the extension part 212 of the first electrode 21 is in contact with the transparent conductive layer 16 through the second openings 32. The pad part 221 of the second electrode 22 is located on the first semiconductor layer 123, the pad part 221 of the second electrode 22 is in contact with the first semiconductor layer 123 through the fourth opening 34, the pad part 221 of the second electrode 22 is in contact with the first semiconductor layer 123 and the protective layer 18, the extension part 222 of the second electrode 22 is located above the second semiconductor layer 125, and the extension part 222 of the second electrode 22 is in contact with the first semiconductor layer 123 through the fifth openings 35 and the through holes 40.

It should be noted that the shape and size of the openings 31 and 34 are not limited to the above description, and they can also directly form a non-annular structure. For example, in some embodiments, there is no protective layer 18 below the center of the pad part of the electrode, and it is in direct contact with the semiconductor stack layer 12. In other embodiments, the openings 31 and 34 can also be designed as a series of finger structures distributed around the pad region, thereby exposing the transparent conductive layer 16, and the pad region does not form an opening structure. In this case, the pad part of the electrode is completely disposed over the protective layer 18 and can be connected to the finger structure through a metal lead.

### Embodiment 2

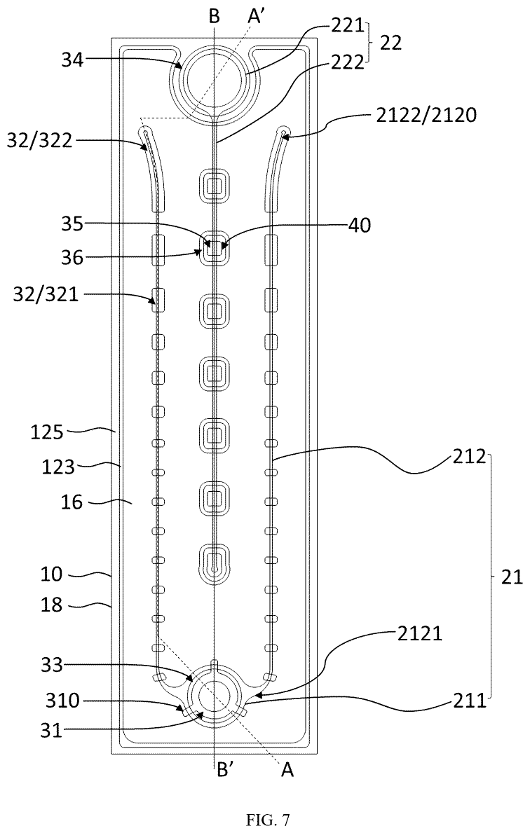

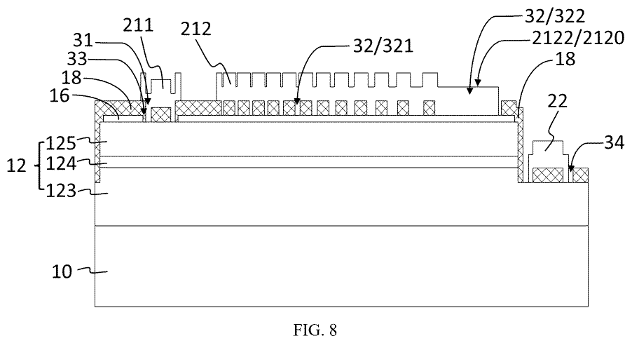

Referring to FIG. 7 and FIG. 8. FIG. 7 illustrates a schematic diagram from a perspective of a top view of a light-emitting diode according to an embodiment 2 of the disclosure, and FIG. 8 illustrates a schematic sectional structural diagram of the light-emitting diode along a A-A′ line in FIG. 7. Compared with the light-emitting diode of other embodiments of the disclosure, the light-emitting diode of the embodiment 2 is different mainly in that, in the embodiment, the size of the multiple second openings 32 of the protective layer 18 increases successively along the extension direction gradually facing away from the pad part 211 of the first electrode 21. Specifically, at a position close to the pad part 211 of the first electrode 21, the size of the second opening 32 is the smallest, and as it moves facing away from the pad part 211 of the first electrode 21, the size of the second openings 32 becomes larger and larger, and the size of the second opening 32 which is farthest from the pad part 211 of the first electrode 21, that is, the size of the second opening 32 located at the second end 2122 of the extension part 212 of the first electrode 21 is the largest. Since the current density tends to gradually increase along the extension direction facing away from the pad part 211 of the first electrode 21, in some embodiments, the design of the second opening 32 gradually increasing in size along the extension direction of the extension part 212 of the first electrode 21 can prevent ESD explosion points from occurring in regions with high current density due to excessive charge concentration, such as near the end of the spreading electrode. At the same time, it can also alleviate the current congestion effect on the first electrode, improve the overall current uniformity of the light-emitting diode, and thereby improving the reliability and the luminous efficiency of the light-emitting diode chip.

### Embodiment 3

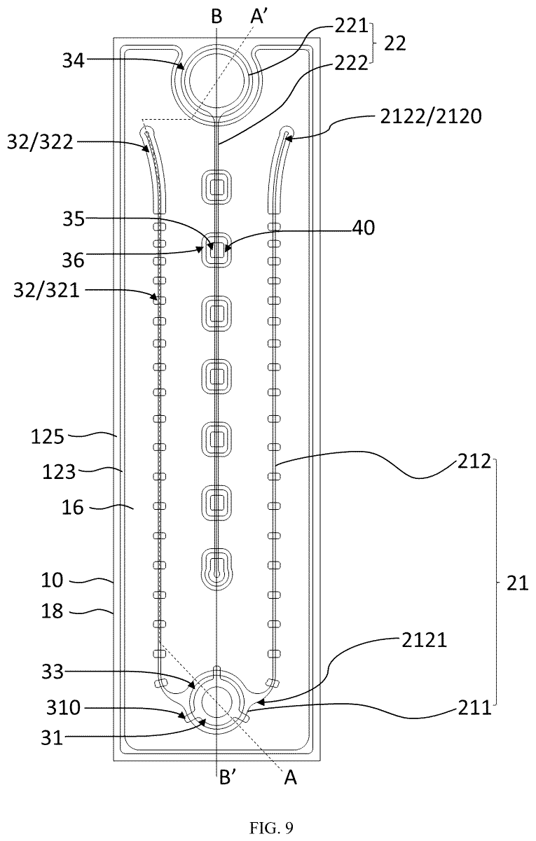

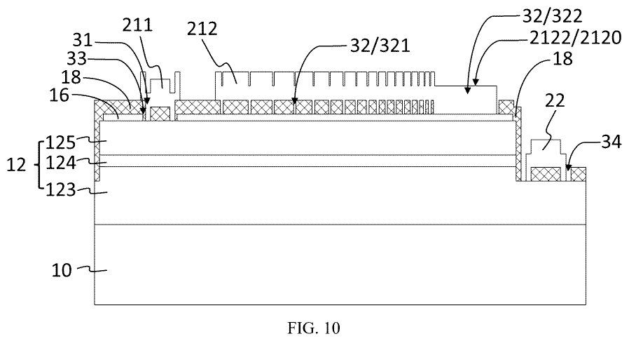

Referring to FIG. 9 and FIG. 10. FIG. 9 illustrates a schematic diagram from a perspective of a top view of a light-emitting diode according to an embodiment 3 of the disclosure, and FIG. 10 illustrates a schematic sectional structural diagram of the light-emitting diode along a A-A′ line in FIG. 9. Compared with the light-emitting diode of other embodiments of the disclosure, the light-emitting diode of the embodiment 3 is mainly different in that, the protective layer 18 has multiple second openings 32, and the second openings 32 are spaced apart from one another by intervals, and the size of the intervals decreases in sequence along the extension direction gradually facing away from the pad part 211 of the first electrode 21. Specifically, at a position closest to the pad part 211 of the first electrode 21, the size of the interval of the second openings 32 is the largest, and as it moves facing away from the pad part 211 of the first electrode 21, the size of the intervals becomes smaller and smaller, and the second openings 32 farthest from the pad part 211 of the first electrode 21, that is, the size of the second opening 32 located at the second end 2122 of the extension part 212 of the first electrode 21 have the smallest interval size. By designing that the intervals of the second openings 32 decrease in sequence along the extension direction of the extension part 212 of the first electrode 21, it is also possible to prevent ESD explosion points from occurring in regions with high current density due to excessive charge concentration. At the same time, it is also possible to improve the overall current uniformity of the light-emitting diode, thereby improving the reliability and the luminous efficiency of the light-emitting diode chip.

Furthermore, in some variant embodiments, there is first intervals among the first opening parts 321, and there is a second interval between the first opening parts 321 and the second opening part 322. The first intervals are the same in size, and the second interval can be larger than the first intervals. This further promotes the current to diffuse more effectively and evenly around the end of the spreading electrode through the large-sized second opening part 322. In some variant embodiments, the size of the first intervals decreases in sequence along the extension direction gradually facing away from the pad part 211 of the first electrode 21, and the size of the second interval can be larger than the size of part or all of the first intervals.

### Embodiment 4

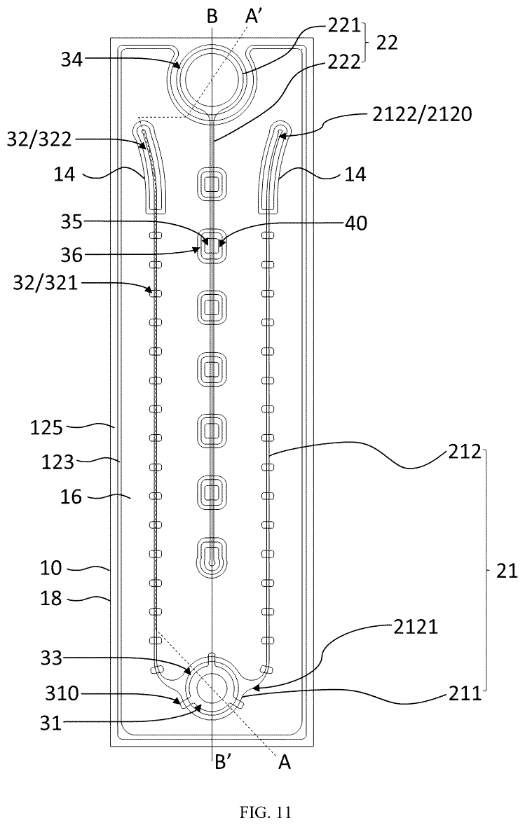

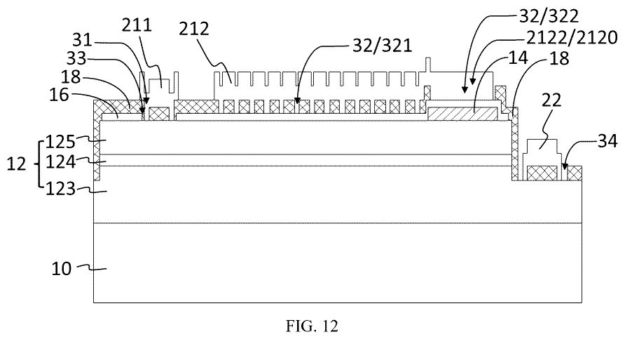

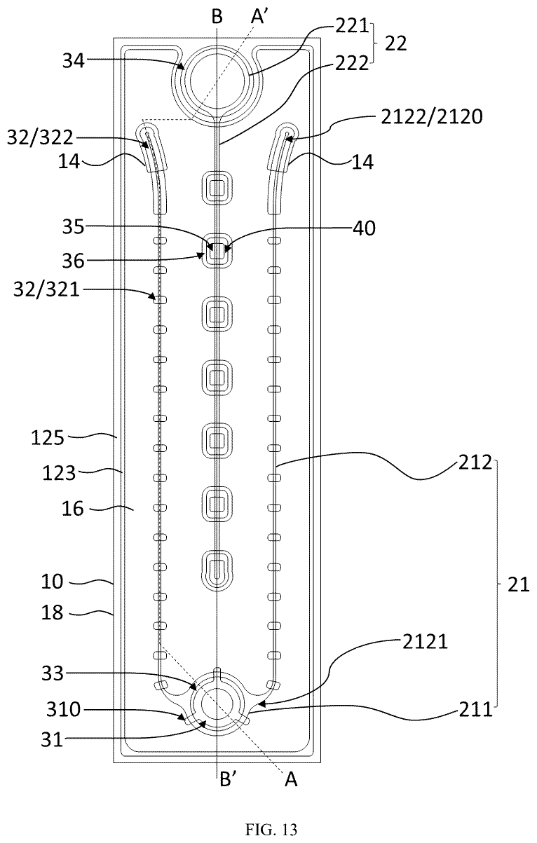

Referring to FIG. 11 to FIG. 18, FIG. 11 illustrates a schematic diagram from a perspective of a top view of a light-emitting diode according to an embodiment 4 of the disclosure, FIGS. 13, 15 and 17 illustrate schematic diagrams from a perspective of a top view of other light-emitting diodes according to the embodiment 4 of the disclosure, and FIGS. 12, 14, 16 and 18 illustrate schematic sectional structural diagrams of the light-emitting diodes along a A-A′ line in FIGS. 11, 13, 15 and 17, respectively. Compared with the light-emitting diode of other embodiments of the disclosure, the light-emitting diode of the embodiment 4 is different mainly in that, the light-emitting diode further includes an insulation layer 14, the insulation layer 14 is disposed over the second semiconductor layer 125, and is sandwiched between the second semiconductor layer 125 and the transparent conductive layer 16. The transparent conductive layer 16 covers the insulation layer 14, and the insulation layer 14 is only formed below the second end 2122 of the extension part 212 of the first electrode 21, and is disposed corresponding to the second opening part 322. The second end 2122 of the extension part 212 of the first electrode 21 is located at an end facing away from the pad part 211 of the first electrode 21. In an embodiment, the insulation layer 14 is only arranged below the end 2120 of the extension part 212 of the first electrode 21. Specifically, the transparent conductive layer 16, the insulation layer 14, and the second semiconductor layer 125 are sequentially disposed below the second end 2122 of the extension part 212 of the first electrode 21, and a part of the protective layer 18, the transparent conductive layer 16, and the second semiconductor layer 125 are sequentially disposed below other regions of the extension part 212 of the first electrode 21. An upper surface of the extension part 212 of the first electrode 21 thus defined is stepped. The light-emitting diode described in the embodiment is designed by correspondingly setting the insulation layer 14 and the second opening part 322, that is, the insulation layer 14 is formed as a current blocking layer only below the second end 2122 of the extension part 212 of the first electrode 21 facing away from the pad part 211 of the first electrode 21. On the one hand, the design of the insulation layer 14 can be used to avoid direct injection of current, further ensuring the reliability of the light-emitting diode. On the other hand, the design can also be used to further promote the current to diffuse more effectively and evenly around the end of the spreading electrode, thereby improving the luminous efficiency of the light-emitting diode chip. In addition, by only setting a small amount of necessary insulation layers, the chip voltage increase caused by the excessive area of the current blocking layer can be avoided. Furthermore, the four-layer structure of the insulation layer 14, the transparent conductive layer 16, the protective layer 18, and the extension part 212 of the first electrode 21 can form a full-angle reflector, thereby improving the reflective ability of the electrode extension region and reducing the light absorption efficiency. Specifically, the insulation layer 14 is an insulation material, which can be an oxide, and can be a relatively transparent material, such as one or more combinations of silicon oxide, titanium oxide, silicon nitride, aluminum oxide, magnesium fluoride, spin-on glass (SOG), polymer (Polymer) and other materials. The disclosure is not limited to the examples listed here. The materials of the insulation layer 14 and the protective layer 18 are both low-refractive index insulation materials, with a refractive index of less than 1.5, and the materials can be the same or different. As an example, in the embodiment, the material of the insulation layer 14 is SiO₂. In an embodiment, a thickness of the insulation layer 14 is in a range of 50 nm to 500 nm.

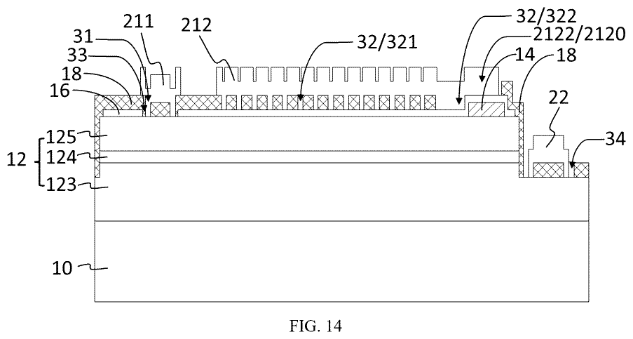

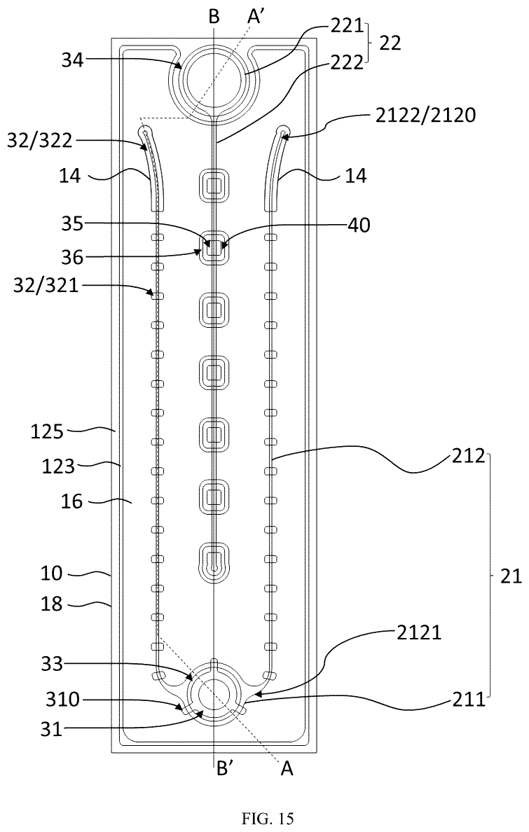

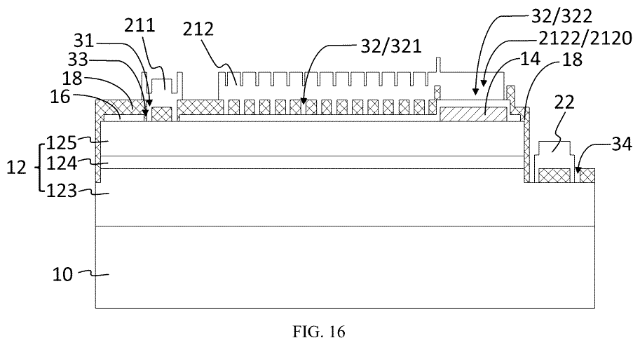

In the disclosure, a width of the insulation layer 14 is greater than or equal to a width of the second opening part 322, so as to enhance the diffusion of the current around the end of the spreading electrode, and further improve the overall current uniformity of the light-emitting diode. It should be noted that in other embodiments, an area of the insulation layer 14 may also be smaller than the area of the second opening part 322, and can be selected and used accordingly according to specific actual needs, and the disclosure is not limited to this. A ratio of the area of the insulation layer 14 to the area of the second opening part 322 is in a range of 10% to 200%. In an embodiment, the ratio is 40% to 150%. In other embodiments, the ratio is 50% to 120%, for example, it can be 50%, 70%, 90% or 110%. Please continue to refer to FIGS. 11 and 12, in the embodiment, the width of the insulation layer 14 is greater than the width of the second opening part 322, and the area of the insulation layer 14 is greater than the area of the second opening part 322. In some modified embodiments, please refer to FIG. 13 and FIG. 14, in the embodiment, the width of the insulation layer 14 is greater than the width of the second opening part 322, and the area of the insulation layer 14 is smaller than the area of the second opening part 322. In some modified embodiments, please refer to FIG. 15 and FIG. 16, in this embodiment, the width of the insulation layer 14 is equal to the width of the second opening part 322, and the area of the insulation layer 14 is equal to the area of the second opening part 322. Through the matching design of the insulation layer 14 at the end of the spreading electrode and the large-sized second opening part 322, the reliability and the luminous efficiency of the light-emitting diode chip are further improved, and at the same time, the voltage increase caused by the excessive area of the current blocking layer can be avoided.

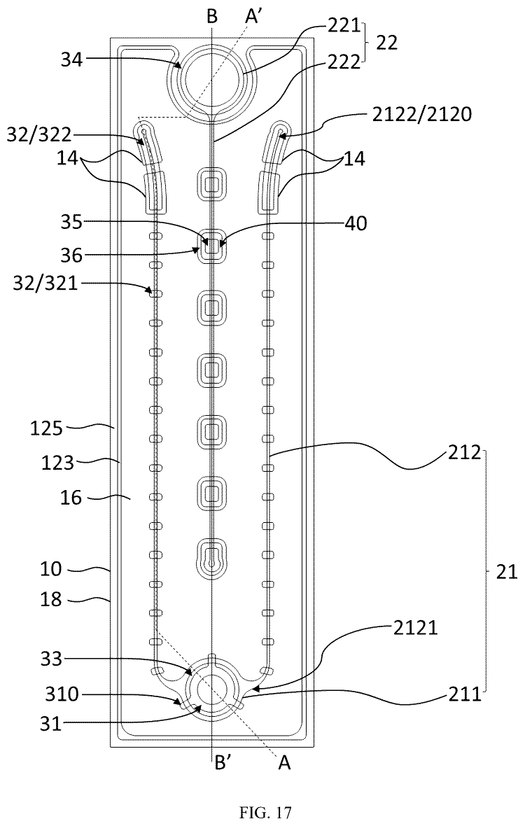

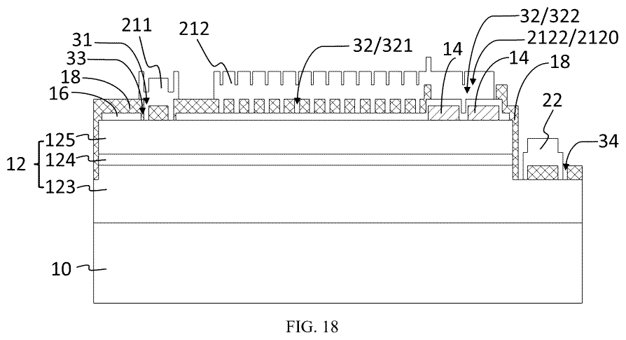

In some embodiments, please refer to FIG. 17 and FIG. 18, the insulation layer 14 is distributed in blocks and is composed of a series of discrete block structures. There are gaps between the block structures, so that the current can not only diffuse to the surroundings at the end of the spreading electrode, but also diffuse through the gaps between the blocks, so that the current diffuses more evenly at the end of the spreading electrode, further improving the overall current uniformity of the light-emitting diode. The areas of multiple block structures can be equal. In some embodiments, the areas of multiple block structures can also be unequal (not shown in drawings). Specifically, when the insulation layer 14 is composed of a series of block structures with unequal areas, the area of the block structure is the largest at the position close to the second end 2122 of the extension part 212 of the first electrode 21, and the area becomes smaller and smaller as it moves facing away from the second end 2122 of the extension part 212 of the first electrode 21, and the area of the block structure farthest from the second end 2122 of the extension part 212 of the first electrode 21 is the smallest. In this way, ESD explosion points can be prevented from occurring in regions with high current density due to excessive charge concentration, such as at the position close to the end of the extended electrode. At the same time, the current congestion effect on the first electrode 21 can be alleviated, the overall current uniformity of the light-emitting diode can be improved, and the reliability and the luminous efficiency of the light-emitting diode chip can be improved.

The disclosure further provides a light-emitting device, including the light-emitting diode described in any of the above embodiments to effectively improve the performance of the light-emitting device.

In summary, the light-emitting diode provided by the disclosure improves the reliability of the chip by designing the second openings of the extension part of the first electrode with differentiated size by positioning the protective layer therein, specifically by increasing the size of the second opening part at the end of the extension part of the first electrode facing away from the pad part of the first electrode.

Finally, it should be noted that the above embodiments are only used to illustrate the technical solutions of the disclosure, rather than to limit it. Although the disclosure has been described in detail with reference to the aforementioned embodiments, those skilled in the art should understand that they can still modify the technical solutions described in the aforementioned embodiments, or replace some or all of the technical features therein with equivalents. However, these modifications or replacements do not cause the essence of the corresponding technical solutions to deviate from the scope of the technical solutions of the embodiments of the disclosure.

What is claimed is:

1. A light-emitting diode, comprising:
a semiconductor stack layer, comprising: a first semiconductor layer, a light-emitting layer and a second semiconductor layer sequentially stacked in that order from bottom to top;
a transparent conductive layer, disposed over the second semiconductor layer;
a protective layer, disposed over the transparent conductive layer; and
a first electrode, disposed over the protective layer, and comprising a first pad part and a first extension part;
wherein the protective layer defines a first opening on the first pad part and defines second openings on the first extension part, and the first electrode is electrically connected to the second semiconductor layer through the first opening and the second openings; and
wherein the second openings of the protective layer comprise a plurality of first opening parts and at least one second opening part, the at least one second opening part is defined on an end of the first extension part facing away from the first pad part, and a size of the at least one second opening part is greater than a size of each of the plurality of first opening parts.

2. The light-emitting diode as claimed in claim 1, wherein the first opening exposes a part of an upper surface of the second semiconductor layer located on the first pad part of the first electrode, and the second openings expose a part of an upper surface of the transparent conductive layer located on the first extension part of the first electrode.

3. The light-emitting diode as claimed in claim 1, wherein the first extension part has a first end connected to the first pad part and a second end facing away from the first pad part, and the at least one second opening part is defined under the second end of the first extension part.

4. The light-emitting diode as claimed in claim 1, wherein the size of each of the plurality of first opening parts is the same.

5. The light-emitting diode as claimed in claim 1, wherein sizes of the plurality of first opening parts gradually increase along a direction extending away from the first pad part of the first electrode.

6. The light-emitting diode as claimed in claim 1, wherein the size of the at least one second opening part is at least twice that of each of the plurality of first opening parts.

7. The light-emitting diode as claimed in claim 1, wherein the size of the at least one second opening part is 2-20 times that of each of the plurality of first opening parts.

8. The light-emitting diode as claimed in claim 1, wherein the second openings are spaced apart from one another by intervals, and the intervals are of equal size.

9. The light-emitting diode as claimed in claim 1, wherein the second openings are spaced apart from one another by intervals, and sizes of the intervals gradually decrease along a direction extending away from the first pad part of the first electrode.

10. The light-emitting diode as claimed in claim 1, wherein the at least one second opening part and the first extension part of the first electrode have an overlapping part, and a length of the overlapping part is 2% to 40% of a length of the first extension part.

11. The light-emitting diode as claimed in claim 1, wherein the at least one second opening part and the first extension part of the first electrode have an overlapping part, and an area of the overlapping part is 2% to 40% of an area of the first extension part.

12. The light-emitting diode as claimed in claim 1, further comprising an insulation layer, wherein the insulation layer is disposed over the second semiconductor layer, and is disposed corresponding to the at least one second opening part, and the transparent conductive layer covers the insulation layer.

13. The light-emitting diode as claimed in claim 12, wherein a width of the insulation layer is greater than or equal to that of the at least one second opening part.

14. The light-emitting diode as claimed in claim 12, wherein a ratio between an area of the insulation layer to an area of the at least one second opening part is in a range of 10% to 200%.

15. The light-emitting diode as claimed in claim 1, wherein the transparent conductive layer defines a third opening on the first pad part of the first electrode, to thereby expose a part of the upper surface of the second semiconductor layer located on the first pad part of the first electrode, and a size of the third opening is smaller than that of the first pad part.

16. The light-emitting diode as claimed in claim 15, wherein a size of the first opening is smaller than that of the third opening, the first pad part of the first electrode is in contact with the second semiconductor layer, and the first extension part of the first electrode is in contact with the transparent conductive layer.

17. The light-emitting diode as claimed in claim 15, wherein the first opening has an annular structure, and an inner diameter and an outer diameter of the annular structure are smaller than a diameter of the third opening.

18. The light-emitting diode as claimed in claim 15, wherein the protective layer further comprises at least one finger extending from the first opening to a periphery of the first pad part of the first electrode, to thereby expose a part of an upper surface of the transparent conductive layer, on a location of the at least one finger, the first pad part of the first electrode is in contact with the second semiconductor layer and the transparent conductive layer simultaneously.

19. The light-emitting diode as claimed in claim 1, further comprising a second electrode, wherein the second electrode comprises a second pad part and a second extension part, the second pad part is located above the first semiconductor layer, the second extension part is located above the second semiconductor layer, the second pad part and the second extension part are in ohmic contact with the first semiconductor layer through a plurality of through holes penetrating through the second semiconductor layer and the light-emitting layer, and the protective layer is disposed between the second extension part and the second semiconductor layer.

20. A light-emitting device, comprising the light-emitting diode as claimed in claim 1.
